(19) United States
(12) Patent Application Publication
(10) Pub. No.: US 2026/0214391 A1
(43) Pub. Date: Jul. 23, 2026

(54) A MICRO-ELECTROMECHANICAL-SYSTEM BASED MICRO SPEAKER

(71) Applicant: MYVOX AB, Stockholm (SE)

(72) Inventors: Josef HANSSON, Vällingby (SE); Edvard KÄLVESTEN, Stockholm (SE); Peter ÅGREN, Huddinge (SE)

(73) Assignee: MYVOX AB, Stockholm (SE)

(21) Appl. No.: 19/138,905

(22) PCT Filed: Nov. 23, 2023
(86) PCT No.: PCT/SE2023/051182

§ 371 Date: Jun. 13, 2025

(30) Foreign Application Priority Data
Dec. 22, 2022 (SE) 2251547-2

(51) Int. Cl. H04R 17/00; B81B 3/00; H04R 1/02; H04R 7/06; H04R 7/18

(52) U.S. Cl. CPC H04R 17/00; B81B 3/0037; H04R 1/023; H04R 7/06; H04R 7/18; B81B 2201/0257; B81B 2203/0118; B81B 2203/019; H04R 2201/003; H04R 2400/11; H04R 2440/01

(57) ABSTRACT

A micro-electromechanical-system based micro speaker contains a support structure and a flexible cantilever configured to be deflected in response to a first control signal influencing at least one first piezoelectric actuator mechanically linked to the flexible cantilever. The flexible cantilever has a base side and at least one edge side. The base side includes an attachment section in which the flexible cantilever is fixed to the support structure, and the at least one edge side is movable relative to the support structure. The flexible cantilever has flat top and bottom surfaces that are parallel to one another and have equally shaped and sized outlines, which generally widen from the base side towards the at least one edge side. Thus, a maximum deflection of the flexible cantilever occurs where it is as widest, which, in turn, enables a comparatively high sound pressure to be produced.

### TECHNICAL FIELD

The present invention relates generally to miniature-sized sound generators. Especially, the invention relates to a micro-electro-mechanical-system (MEMS) based micro speaker according to the preamble of claim 1.

### BACKGROUND

The vibration amplitude is a limiting factor for producing sound pressure from small membrane speakers. This is especially the case at lower frequencies. In general, a larger diaphragm diameter enables a given sound-pressure-level (SPL) at a smaller deflection amplitude. In other words, increased vibration amplitude allows for smaller speakers at the same level of performance.

MEMS based micro speakers are emerging as new technology. In this field, the piezoelectric MEMS micro speaker appear to be the most promising alternative. In its most basic configuration a piezoelectric MEMS micro speaker has a silicon membrane, which is obtained by etching a backside cavity from a silicon chip, and which is actuated by a piezoelectric layer on top of the membrane. The piezoelectric layer is capable to produce high forces. However, for this type of speaker, the vibration amplitude is limited by the tensile tension in the membrane. Moreover, silicon is a relatively stiff material, which also hampers the total amplitude.

One way to increase the deflection is to create slits in the membrane as suggested in the article Stoppel, A., Männchen, F. Niekiel, D. Beer, T. Giese and B. Wagner, New integrated full-range MEMS speaker for in-ear applications, 2018 IEEE Micro Electro Mechanical Systems (MEMS), 2018, pp. 1068-1071, doi: 10.1109/MEMSYS.2018.8346744, which discloses a type of powerful and fully integrated piezoelectric MEMS speaker for in-ear applications. Measurements performed on first prototypes using an artificial ear simulator have revealed a remarkable acoustic performance with respect to SPL, reproduction range, total harmonic distortion (THD) and electroacoustic sensitivity. Due to the mechanically decoupled design without a closed membrane, high SPL values of about 110 dB are achieved from 20 Hz to 20 KHz, exceeding the reproduction range of typical electrodynamic and balanced armature speakers. At the same time, the MEMS speakers feature a very flat frequency response, which has been realized by means of electronic equalization. With respect to the reproduction quality, the speakers are capable of delivering low THD of less than 2% for most frequencies. Moreover, electroacoustic sensitivity measurements have proven good energy efficiency with sensitivity values surpassing 110 dB/mW within almost the entire audible frequency range.

Nevertheless, providing slits in the membrane makes the speaker more different from a closed-membrane ditto. Instead, in such a slitted-membrane speaker, the speaker rather behaves like multiple cantilevers facing one another. Although here, the deflection is not limited by tensile stress in the membrane, however by the bending stiffness.

Especially for larger deflections, the gaps between the cantilevers cause air to leak out. At least partially, this effect counteracts the sound pressure being produced.

The above-mentioned air leakage may be avoided by the strategy for obtaining high sound-pressure-level MEMS speakers via a rigid-flexible vibration coupling mechanism of unsealed piezoelectric cantilevers and a sealed Parylene C membrane described in the article Q. Wang, Z, Yi, T. Ruan, Q. Xu, B. Yang, J. Lui, Obtaining High SPL Piezoelectric MEMS Speaker via a Rigid-flexible Vibration Coupling Mechanism, Journal of Microeletromechanical Systems, Volume 30, No. 5, 2021, DOI: 10.1109/JMEMS.2021. 3087718. Here, the speaker comprises six identical triangular vibration cantilevers elements arranged to form a regular hexagonal vibration membrane with a side length of 2 mm. The speaker has a PZT thin film layer and Pt layers as upper and lower electrodes; its elastic actuator layer is a SiO₂/Si/SiO₂/Si multilayer composite film, and its substrate is an SOI one. To form the rigid-flexible-coupling sealed vibration membrane, Parylene C is deposited on the vibration cantilever surfaces and the sidewalls and bottoms of the etched gaps before etching the back cavity. Compared with the SPL of the designed speaker with no deposited flexible Parylene C at a driving voltage of 2 V, the SPL produced by the speaker with the rigid-flexible-coupling sealed vibration membrane increased by 3-12.2 dB.

Thus, covering the piezoelectric cantilevers with a flexible polymer film that seals the vibration membrane to the surrounding side walls may improve the efficiency of a MEMS based speaker fairly much. However, this design is associated with its own shortcomings, for instance energy losses resulting from stretching the polymer film.

Consequently the known MEMS based micro speaker designs leave room for further improvements.

### SUMMARY

The object of the present invention is therefore to offer an improved solution that enables higher sound pressures while maintaining the small physical size of the micro speaker.

According to the invention, the object is achieved by a MEMS-based micro speaker containing a support structure and a flexible cantilever configured to be deflected in response to a first control signal influencing at least one first piezoelectric actuator mechanically linked to the flexible cantilever. The flexible cantilever has a base side and at least one edge side. The base side has an attachment section in which the flexible cantilever is fixed to the support structure, and the at least one edge side is movable relative to the support structure. The support structure has a frame part that surrounds the flexible cantilever, i.e. the base side as well as each of the at least one edge side. Further, the flexible cantilever includes flat top and bottom surfaces that are parallel to one another and have equally shaped and sized outlines, which generally widen from the base side towards the at least one edge side.

The above MEMS-based micro speaker is advantageous because a key factor for generating high sound pressure levels is the overall average deflection of the flexible cantilever, and in the proposed design a maximum deflection of the flexible cantilever occurs where it is as widest. This, in turn, enables high sound pressure levels from relatively small-sized designs.

The at least one first piezoelectric actuator may contain at least one polarized piezoelectric layer and one intrinsic layer. Said layers are configured to cause the at least one first piezoelectric actuator to bend in a first direction in response to the first control signal applied between terminals connected to the at least one polarized piezoelectric layer respective to a point electrically isolated therefrom by the intrinsic layer, if the first control signal carries a voltage of a first magnitude relative to a reference voltage. Conversely, if the first control signal carries a voltage of a second magnitude being opposite to the first magnitude in relation to the reference voltage, the at least one first piezoelectric actuator is configured to bend in a second direction, which is opposite to the first direction.

According to one embodiment of the invention, a flexible polymer membrane covers a gap distance between each of the at least one edge side of the flexible cantilever and the frame part of the support structure. Thus, although there is spacing between the flexible cantilever and the frame part of the support structure, fluid leakage between the flexible cantilever and the support structure is efficiently prevented. This, in turn, enhances the overall sound-producing efficiency of the design.

According to embodiments of the invention, the base side has a rectilinear outline, and possibly a first edge side with a curved outline, which for example is arranged opposite to the base side. Inter alia, this allows for rounded speaker designs suitable for in-ear applications.

According to another embodiment of the invention, the flexible cantilever includes a first edge side that has a rectilinear outline and is parallel to the base side. This shape is advantageous because it provides a widest possible cantilever shape where maximum deflection occurs. For similar reasons, the first edge side is preferably longer than the base side irrespective which outline the first edge side has.

According to yet another embodiment of the invention, the flexible cantilever contains second and third edge sides that connect the first edge side with the base side. Although this outline is compatible with one or more side edges having a curved outline, the second and third edge sides preferably have rectilinear outlines because thereby a largest possible area of the speaker may be covered by one or more flexible cantilevers, which, in turn, vouches for a high SPL.

According to still another embodiment of the invention, the MEMS-based micro speaker includes two instances of the flexible cantilever, which may either have the same or different outlines. In any case, each of the flexible cantilevers is fixed to a frame part of the support structure via a respective attachment section. Thus, the flexible cantilevers may be controlled independently of one another.

According to further embodiments of the invention, the MEMS-based micro speaker includes at least two flexible cantilevers, and each of them is fixed to a central part of the support structure via a respective attachment section. The central part of the support structure may, in turn, be connected to a frame part of the support structure via at least two flexible support arms, which each is mechanically linked to a respective at least one second piezoelectric actuator controllable in response to at least one second control signal. Consequently, it is also possible to influence a position of the central part of the support structure along an axis perpendicular to a plane represented by the frame part of the support structure. This is beneficial since it allows for even larger overall deflection amplitudes. It is also rendered possible to produce sounds at different frequencies simultaneously. Additionally, for further flexibility, at least two flexible cantilevers may be included, which each is fixed to the central part of the support structure via a respective attachment section.

According to yet another embodiment of the invention, each of the at least two flexible support arms is specifically configured to be deflected in response to the at least one second control signal such that, in a first extreme positioning of the at least two instances of flexible cantilevers, the at least one edge side edge side thereof reaches a first maximum distance from the frame part of the support structure in a first direction parallel to the axis perpendicular to the plane represented by the frame part of the support structure. Analogously, in a second extreme positioning of the at least two instances of flexible cantilevers, the at least one edge side thereof reaches a second maximum distance from the frame part of the support structure in a second direction parallel to the axis perpendicular to the plane represented by the frame part of the support structure, which second direction is opposite to the first direction. As a result, very large deflection amplitudes are attainable.

According to still another embodiment of the invention, the MEMS-based micro speaker includes a flexible polymer membrane covering the flexible cantilever and the support structure. The flexible polymer membrane is arranged to prevent fluid leakage between the flexible cantilever and the support structure such that in a first extreme positioning of the flexible cantilever, the flexible polymer membrane is folded to form a fold between the at least one edge side of the flexible cantilever and the frame part of the support structure, and in a second extreme positioning of the flexible cantilever, the flexible polymer membrane is unfolded to cover a spacing between the at least one edge side of the flexible cantilever and the frame part of the support structure. Consequently, while avoiding air leakage, only a small amount of energy is required to stretch the flexible polymer membrane, and therefore a relatively large amount of the supplied energy may be used to produce sound.

Alternatively, according to another embodiment of the invention, the at least one edge side of the flexible cantilever is movable relative to the support structure between first and second extreme positionings with respect to first and second distances along an axis perpendicular to a plane represented by the frame part of the support structure, and the frame part is arranged relative to the attachment section of the flexible cantilever and has such an extension along the above-mentioned axis that in each of the first and second extreme positionings a gap distance between said frame part and the at least one edge side is less than a threshold distance. Thereby, the effective air leakage may be kept low also without the flexible polymer membrane.

According to further embodiments of the invention, the flexible cantilever contains at least one beam member arranged in parallel with the first edge side. The at least one beam member is configured to reduce bending of flexible cantilever in directions parallel to the first edge side. Thus, the flexible cantilever may be restricted to only bend perpendicularly or radially with respect to the base side. This is generally desirable when producing low-distortion sound at high efficiency.

Further advantages, beneficial features and applications of the present invention will be apparent from the following description and the dependent claims.

### BRIEF DESCRIPTION OF THE DRAWINGS

The invention is now to be explained more closely by means of preferred embodiments, which are disclosed as examples, and with reference to the attached drawings.

FIGS. 1a-b show a MEMS-based micro speaker according to a first embodiment of the invention;

FIGS. 2a-b show a MEMS-based micro speaker according to a second embodiment of the invention;

FIGS. 3a-b show a MEMS-based micro speaker according to a third embodiment of the invention;

FIG. 4 illustrates a design of a piezoelectric actuator according to the first and second embodiments of the invention;

FIG. 5 illustrates a design of a piezoelectric actuator according to the third embodiment of the invention;

FIGS. 6a-e show a MEMS-based micro speaker according to a fourth embodiment of the invention;

FIGS. 7a-c illustrate how a piezoelectric actuator for controlling a flexible cantilever may be designed according embodiments of the invention;

FIG. 8 shows a MEMS-based micro speaker according to a fifth embodiment of the invention;

FIG. 9 shows a MEMS-based micro speaker according to a sixth embodiment of the invention;

FIG. 10 shows a MEMS-based micro speaker according to a seventh embodiment of the invention;

FIG. 11 shows a MEMS-based micro speaker according to an eighth embodiment of the invention;

FIGS. 12a-b show a MEMS-based micro speaker according to a ninth embodiment of the invention;

FIGS. 13a-b show a MEMS-based micro speaker according to a tenth embodiment of the invention;

FIGS. 14a-b show a MEMS-based micro speaker according to an eleventh embodiment of the invention;

FIGS. 15a-b show a MEMS-based micro speaker according to a twelfth embodiment of the invention; and

FIGS. 16a-b show a MEMS-based micro speaker according to a thirteenth embodiment of the invention.

### DETAILED DESCRIPTION

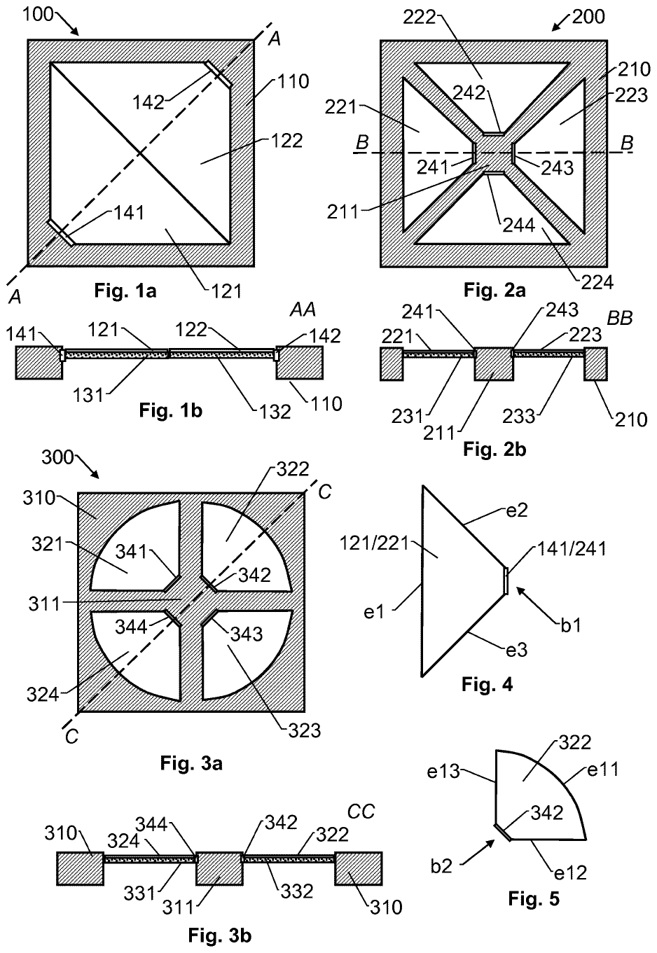

In FIG. 1a we see a top view of a MEMS-based micro speaker according to a first embodiment of the invention and FIG. 1b shows a side view of this speaker along a cross section AA.

The MEMS-based micro speaker has a support structure 100 and two flexible cantilevers 131 and 132 respectively. The support structure 100, in turn, has a frame part 110 that surrounds the flexible cantilevers 131 and 132. Each of the flexible cantilevers 131 and 132 is configured to be deflected in response to a first control signal influencing a respective first piezoelectric actuator 121 and 122 being mechanically linked to the flexible cantilevers 131 and 132 respectively. As is apparent from FIG. 1b, the piezoelectric actuators 121 and 122 are arranged below the flexible cantilevers 131 and 132. However, since the piezoelectric actuators 121 and 122 are configured to cause the flexible cantilevers 131 and 132 to deflect equally much in opposite directions, the piezoelectric actuator 121 and 122 may alternatively also be arranged on top of the flexible cantilevers 131 and 132.

Referring now to FIGS. 7a to 7c, we see a schematic side view illustrating how a piezoelectric actuator 700 for controlling a flexible cantilever may be designed according embodiments of the invention. The first piezoelectric actuator 700 here contains first and second piezoelectric layers 701 and 702 respectively of opposite polarities, which are separated by an intrinsic layer 703. In the illustrated example, we presume that the first piezoelectric layer 701 is an n-type piezo-layer, the second piezoelectric layer 702 is a p-type piezo-layer and the intrinsic layer 703 is an undoped piezo-layer.

The layers 701, 702 and 703 are configured to cause the piezoelectric actuator 700 to bend in first and second directions D1 and D2 respectively. Specifically, in response to a first control signal CS applied between terminals 711 and 712 connected to the first and second piezoelectric layers 701 and 702 respectively, which first control signal CS carries a voltage of a first magnitude relative to a reference voltage, for example-V relative to a zero DC level, creates an electric field between the first and second piezoelectric layers 701 and 702 that causes the piezoelectric actuator 700 to bend in the first direction D1. Analogously, in response to the first control signal CS carrying a voltage of a second magnitude being opposite to the first magnitude in relation to the reference voltage, for example +V relative to the zero DC level, a reversely directed electric field between the first and second piezoelectric layers 701 and 702 causes the piezoelectric actuator 700 to bend in the second direction D2 being opposite to the first direction D1.

It should be noted that, according to embodiments of the invention, the reference voltage may equally well have a non-zero value. In other words, the reference voltage may be any positive or negative DC level suitable for the implementation.

As an alternative to the above, the piezoelectric actuator 700 may contain only a single polarized piezoelectric layer, i.e. of p- or n-type, and one intrinsic layer arranged on one side of the piezoelectric actuator. In other words, besides the intrinsic layer 703, the piezoelectric actuator 700 exclusively contains the first piezoelectric layers 701 or the second piezoelectric layer 702. In such a case, the first terminal 711 is connected to the polarized piezoelectric layer and the second terminal 712 is connected to a point electrically isolated therefrom by the intrinsic layer 703.

FIG. 4 shows a top view of one of the flexible cantilevers 121 in FIG. 1b. According to the invention, the flexible cantilever 121 has a base side b1 and at least one edge side, which in FIG. 4 are exemplified by e1, e2 and e3 respectively. The base b1, which preferably has a rectilinear outline side includes an attachment section 141 in which the flexible cantilever 121 is fixed to the support structure 100. The edge sides e1, e2 and e3, however, are movable relative to the support structure 100 along with the flexible cantilever 121. The flexible cantilever 121 has flat top and bottom surfaces that are parallel to one another and have equally shaped and sized outlines which generally widen from the base side b1 towards the edge sides e1, e2 and e3, for example as illustrated in FIGS. 1a and 4.

According to other embodiments of the invention, the flexible cantilever may have other outlines which generally widen from the base side towards the edge side and/or the number of flexible cantilevers comprised in the MEMS-based micro speaker may vary, for example ranging from one to eight instances, which may either have identical outlines, or have outlines that are mutually different from one another.

FIGS. 2a and 2b show a MEMS-based micro speaker according to a second embodiment of the invention. Similar to the embodiment shown in FIGS. 1a and 1b, the flexible cantilevers here have rectilinear outlines, i.e. with a base side b1 and edge sides e1, e2 and e3 respectively as illustrated in FIG. 4. However, in the second embodiment of the invention, the MEMS-based micro speaker contains four flexible cantilevers 231, 232, 233 and 234, each of which is mechanically linked to a respective piezoelectric actuator of which two are shown in the cross section view BB of FIG. 2b in the form of 231 and 233 respectively. Further, each of the base sides b1 includes a respective attachment section 241, 242, 243 and 244 in which the respective flexible cantilever 231, 232, 233 and 234 is fixed to the support structure 200.

Here, the each of the flexible cantilevers 231, 232, 233 and 234 is fixed to a central part 211 of the support structure 200, and analogous to the above, the flexible cantilevers 231, 232, 233 and 234 are fixed via a respective attachment section 241, 242, 243 and 244. Further, the support structure has a frame part 210 that surrounds the flexible cantilevers 231, 232, 233 and 234.

Preferably, in the embodiments of FIGS. 1a to 2b, the first edge side e1 is parallel to the base side b1. Namely, this simplifies the manufacture and leads to high energy efficiency due to the fact that, within an available physical space, the part of the flexible cantilevers that is subjected to maximum deflection may also be made as wide as possible.

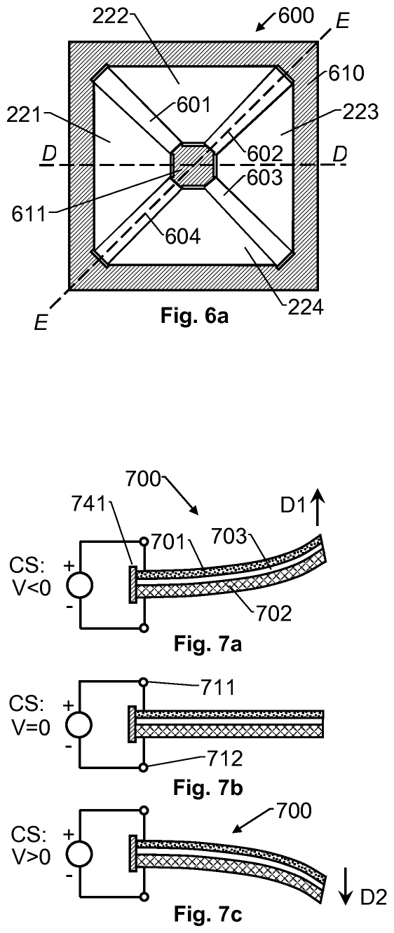

FIGS. 3a and 3b show a MEMS-based micro speaker according to a third embodiment of the invention. Similar to the embodiment shown in FIGS. 2a and 2b, the speaker here contains four flexible cantilevers in the form of 321, 322, 323 and 324 respectively that are fixed to a central part 311 of a frame structure 300 via a respective attachment section 341, 342, 343 and 344, and the support structure has a frame part 310 that surrounds the flexible cantilevers 321, 322, 323 and 324. However, in contrast to the previously discussed embodiments, in the embodiment illustrated in FIGS. 3a and 3b, each of the flexible cantilevers 321, 322, 323 and 324 has a first edge side e11 with a curved outline as illustrated in FIG. 5.

Second and third edge sides e12 and e13 respectively of each flexible cantilever 322 connect the first edge side e11 with the base side b2. Further, each flexible cantilever of the flexible cantilevers 321, 322, 323 and 324 has flat top and bottom surfaces that are parallel to one another and have equally shaped and sized outlines which generally widen from the base side b2 towards the edge sides e11, e12 and e13.

Thus, irrespective of whether the first edge side e1 or e11 has a rectilinear or curved outline, e.g. as illustrated in FIG. 4 or 5 respectively, the first edge side e1 or e11 is preferably longer than the base side b1 or b2 respectively. However, naturally, according to the invention, the flexible cantilever may have alternative outlines for example containing side edges in addition to the above-described examples in the form of e1, e2 and e3 or e11, e12 and e13 respectively; and if so, the outline need not necessarily include a single first side edge being longer that the base side.

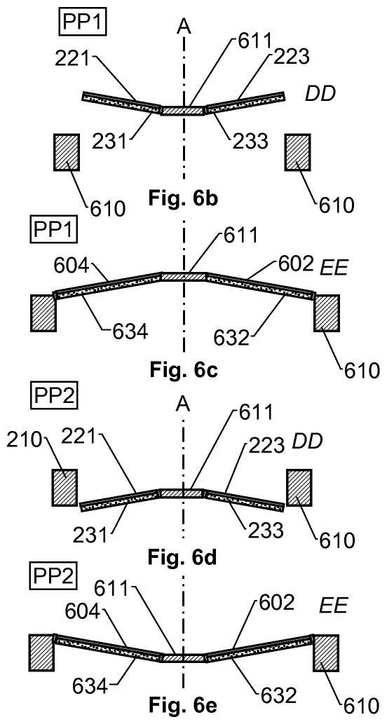

FIGS. 6a to 6e show a MEMS-based micro speaker according to a fourth embodiment of the invention. Here, a central part 611 of a support structure 600 is connected to a frame part 610 of the support structure 600 via four flexible support arms, which each is mechanically linked to a respective piezoelectric actuator 601, 602, 603 and 604 controllable in response to at least one second control signal, for instance as described above referring to FIGS. 7a to 7c, so as to influence a position of the central part 611 of the support structure 600 along an axis A perpendicular to a plane represented by the frame part 610 of the support structure 600. Analogous to the above, the frame part 610 sur-rounds the flexible cantilevers 231 and 233 (and 222 and 224).

FIG. 6a shows a top view of the MEMS-based micro speaker, FIGS. 6b and 6d show side views thereof along a first cross section DD, and FIGS. 6c and 6e show side views thereof along a second cross section EE along a diagonal of the support structure 600.

In FIG. 6b, the flexible cantilevers 221 and 223 (and preferably also 222 and 224) are controlled to a first extreme positioning PP1, where the edge sides e1, e2 and e3 of the flexible cantilevers reach a first maximum distance from the frame part 610 of the support structure 600 in a first direction parallel to the axis A perpendicular to the plane represented by the frame part of the support structure. FIG. 6c shows the same situation as FIG. 6b, however along the second cross section EE, when also the piezoelectric actuators 601, 602, 603 and 604 have been controlled to the first extreme positioning PP1. Consequently, the central part 611 is likewise located in a first extreme position, and the first maximum distance between the edge sides e1, e2 and e3 and the frame part 610 therefore becomes substantial.

In FIG. 6d, the flexible cantilevers 221 and 223 (and preferably also 222 and 224) are controlled to a second extreme positioning PP2, where the edge sides e1, e2 and e3 of the flexible cantilevers reach a second maximum distance from the frame part 610 of the support structure 600 in a second direction parallel to the axis A perpendicular to the plane represented by the frame part of the support structure, which second direction is opposite to the first direction. FIG. 6e shows the same situation as FIG. 6b, however along the second cross section EE, when also the piezoelectric actuators 601, 602, 603 and 604 have been controlled to the second extreme positioning PP2. Consequently, the central part 611 is likewise located in a second extreme position, and the second maximum distance between the edge sides e1, e2 and e3 and the frame part 610 also becomes substantial in this direction.

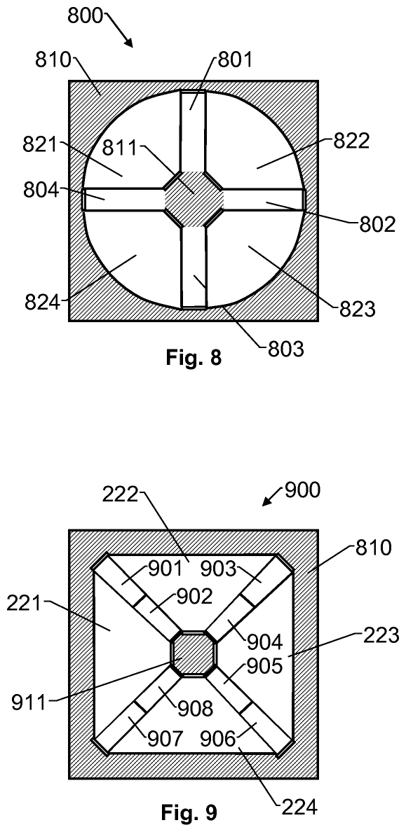

FIG. 8 shows a MEMS-based micro speaker according to a fifth embodiment of the invention, where a central part 811 of a support structure 800 is connected to a frame part 810 of the support structure 800 via four flexible support arms. Each of the four flexible support arms is mechanically linked to a respective second piezoelectric actuator 801, 802, 803 and 804 that is controllable in response to at least one second control signal, e.g. CS as exemplified in FIGS. 7a to 7c, so as to influence a position of the central part 811of the support structure 800 along the axis A perpendicular to a plane represented by the frame part 810 of the support structure (cf. the discussion above with reference to FIGS. 6a to 6e). Moreover, analogous to the above, the MEMS-based micro speaker contains four flexible cantilevers 821, 822, 823 and 824 respectively, which each is fixed to the central part 811 of the support structure 800 via a respective attachment section and is mechanically linked to a respective piezoelectric actuator controllable in response to the first control signal, such that the four flexible cantilevers 821, 822, 823 and 824 are movable relative to the central part 811. The frame part 810 surrounds the flexible cantilevers 821, 822, 823 and 824.

FIG. 9 shows a MEMS-based micro speaker according to a sixth embodiment of the invention, where a central part 911 of a support structure 900 is connected to a frame part 910 of the support structure 900 via four flexible support arms. Here, each of the four flexible support arms is mechanically linked to two respective second piezoelectric actuators, namely 901 and 902 on a first flexible support arm, 903 and 904 on a second flexible support arm, 905 and 906 on a third flexible support arm, and 907 and 908 on a fourth flexible support arm. Each of said second piezoelectric actuators is controllable in response to a second set of control signals, e.g. CS as exemplified in FIGS. 7a to 7c, so as to influence a position of the central part 911 of the support structure 900 along the axis A perpendicular to a plane represented by the frame part 910 of the support structure (cf. the discussion above with reference to FIGS. 6a to 6e). The frame part 910 surrounds the flexible cantilevers 221, 122, 223 and 224. Said doubled second piezoelectric actuators on each of the flexible support arms enable highly complex movements of the of the central part 911. In particular, these movements may be transferred to the four flexible cantilevers 221, 122, 223 and 224, which analogous to the above, are fixed to the central part 911 via a respective attachment section and are mechanically linked to a respective piezoelectric actuator controllable in response to the first control signal, such that the four flexible cantilevers 221, 222, 223 and 224 are movable relative to the central part 911.

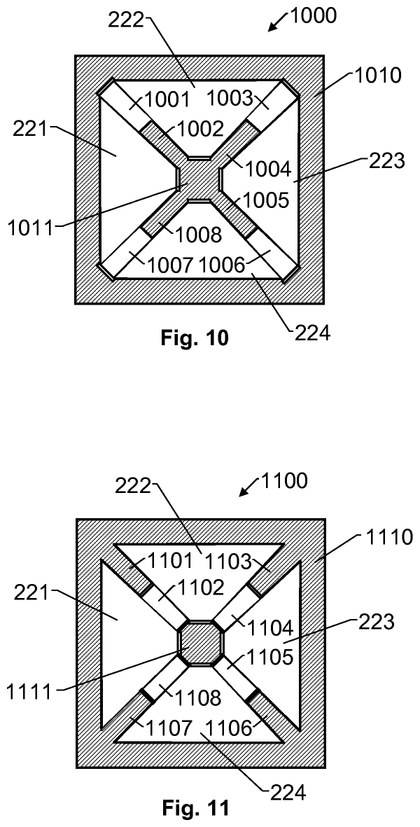

FIG. 10 shows a MEMS-based micro speaker according to a seventh embodiment of the invention, where a central part 1011 of a support structure 1000 is connected to a frame part 1010 of the support structure 1000 via four flexible support arms. The frame part 1010 surrounds the flexible cantilevers 221, 122, 223 and 224. The design is thus similar to the sixth embodiment described above. Here, however, each of the four flexible support arms has a first part respectively that is flexibly connected to the frame part 1010 and a second part 1002, 1004, 1005 and 1008 that is rigidly connected to the a central part 1011. Each of the first parts is mechanically linked to a respective second piezoelectric actuator 1001, 1003, 1006 and 1007 is controllable in response to a respective second control signal, e.g. CS as exemplified in FIGS. 7a to 7c, so as to influence a position of the central part 1011 of the support structure 1000 along the axis A perpendicular to a plane represented by the frame part 1010 of the support structure (cf. the discussion above with reference to FIGS. 6a to 6e). Hence, somewhat less complex movements of the of the central part 1011 are possible than in the sixth embodiment. However, the speaker design is rendered less complex. Of course, analogous to the above, the seventh embodiment of the invention includes flexible cantilevers 221, 122, 223 and 224, are fixed to the central part 1011 via a respective attachment section and are mechanically linked to a respective piezoelectric actuator controllable in response to the first control signal, such that the four flexible cantilevers 221, 222, 223 and 224 are movable relative to the central part 1011.

FIG. 11 shows a MEMS-based micro speaker according to an eighth embodiment of the invention. where a central part 1111 of a support structure 1100 is connected to a frame part 1110 of the support structure 1100 via four flexible support arms. The frame part 1110 surrounds the flexible cantilevers 221, 222, 223 and 224. The design is thus similar to the above-described seventh embodiment. Here, however, the first part 1101, 1103, 1106 and 1107 respectively of each of the four flexible support arms is rigidly connected to the frame part 1110 and the second part is flexibly connected to the a central part 1111 via a respective attachment section. Each of the second parts is mechanically linked to a respective second piezoelectric actuator 1101, 1103, 1106 and 1107 is controllable in response to a respective second control signal, e.g. CS as exemplified in FIGS. 7a to 7c, so as to influence a position of the central part 1011 of the support structure 1100 along the axis A perpendicular to a plane represented by the frame part 1110 of the support structure (cf. the discussion above with reference to FIGS. 6a to 6e). Thereby, relatively complex movements of the of the central part 1111 are possible, and still the speaker design is comparatively uncomplex. Of course, analogous to the above, the eighth embodiment of the invention includes flexible cantilevers 221, 122, 223 and 224, are fixed to the central part 1011 via a respective attachment section and are mechanically linked to a respective piezoelectric actuator controllable in response to the first control signal, such that the four flexible cantilevers 221, 222, 223 and 224 are movable relative to the central part 1111.

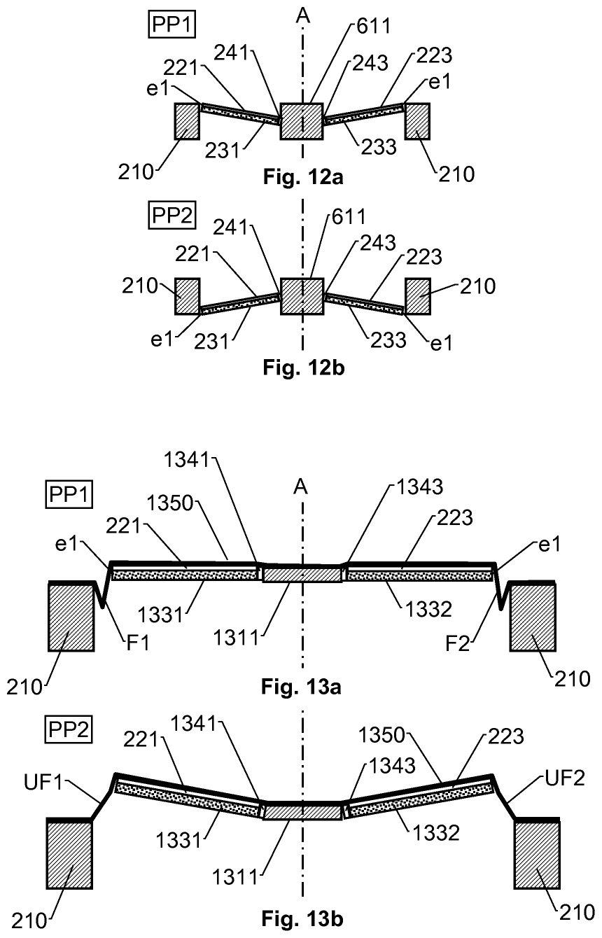

FIGS. 12a and 12b show a MEMS-based micro speaker according to a ninth embodiment of the invention, where the edge sides, here exemplified by the first edge side e1, of a pair of flexible cantilevers 231 and 232 are movable relative to the support structure, here exemplified by the frame part 210, between first and second extreme positionings PP1 and PP2 respectively with respect to first and second distances along an axis A perpendicular to a plane represented by the frame part 210 of the support structure. The frame part 210 is arranged relative to the attachment sections 241 and 242 of the flexible cantilevers 231 and 232 respectively and has such an extension along the axis A that in each of the first and second extreme positionings PP1 and PP2 a gap distance between said frame part 210 and the first edge side e1 is less than a threshold distance, say 0.1 mm. Consequently, the air leakage between the flexible cantilevers 231 and 232 and the frame part 210 may be held low, and therefore the speaker can produce a high SPL in an efficient manner.

FIGS. 13a and 13b show a MEMS-based micro speaker according to a tenth embodiment of the invention, where air leakages are prevented in an alternative way. Here, a flexible polymer membrane 1350 covers a pair of flexible cantilevers 1331 and 1332 respectively and a support structure, which is exemplified by a central part 1311 and the frame part 210. The flexible polymer membrane 1350 is arranged to prevent fluid leakage between the flexible cantilever and the support structure as follows. In a first extreme positioning PP1 of the flexible cantilevers 1331 and 1332, for example in which the edge sides e1 of the flexible cantilevers 1331 and 1332 are located close to the frame part 210. In a second extreme positioning PP2 of the flexible cantilevers 1331 and 1332, the flexible polymer membrane 1350 is unfolded to cover a spacing UF1 and UF2 respectively between the edge sides e1 and the frame part 210 of the support structure. This folding and unfolding of the flexible polymer membrane 1350 is advantageous because it typically results in less energy losses than stretching the flexible polymer membrane 1350 over the edge sides e1.

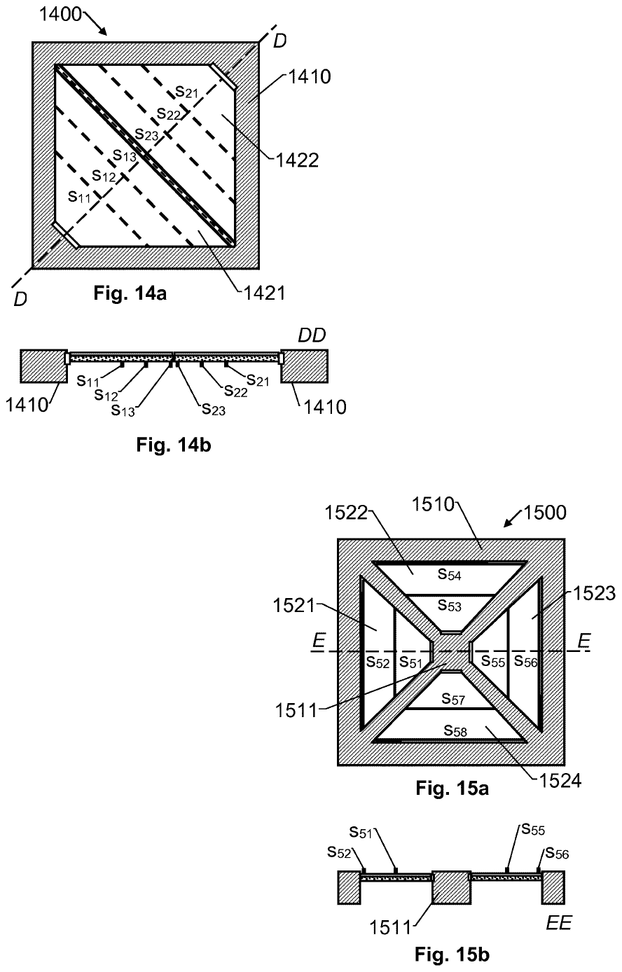

FIGS. 14a to 16b show different embodiments of the MEMS-based micro speaker according to the invention, where the flexible cantilevers contain one or more beam members configured to reduce undesired bending of the flexible cantilevers during operation of the speaker.

Specifically, FIG. 14a shows a top view of the MEMS-based micro speaker corresponding to the embodiment of FIG. 1a, and FIG. 14b shows a section side view corresponding to FIG. 1b. Here, however, the first flexible cantilever 131 contains a first set of beam members s₁₁, s₁₂ and s₁₃, that is arranged on a bottom side thereof and in parallel with the first edge side e1. Each of the beam members s₁₁, s₁₂ and s₁₃ is configured to reduce bending of flexible cantilever in directions parallel to the first edge side e1. Thus, the first edge side e1 will be held relatively parallel to a frame part 1410 of the support structure throughout a flexion movement of the first flexible cantilever 131 between first and second extreme positions. The frame part 1410 surrounds the first and second flexible cantilevers 131 and 132 respectively. The second flexible cantilever 132 contains a second set of beam members s₂₁, s₂₂ and s₂₃, that is arranged on a bottom side thereof and in parallel with the first edge side e1. Each of the beam members s₂₁, s₂₂ and s₂₃ is likewise configured to reduce bending of flexible cantilever in directions parallel to the first edge side e1 so that the first edge side e1 is held relatively parallel to a frame part 1410 of the support structure throughout a flexion movement of the second flexible cantilever 132 between first and second extreme positions.

FIG. 15a shows a top view of the MEMS-based micro speaker corresponding to the embodiment of FIG. 2a, and FIG. 15b shows a section side view corresponding to FIG. 2b, however where the flexible cantilevers contain a respective set of beam members s₅₁, s₅₂, s₅₃, s₅₄, s₅₅, s₅₆, s₅₇, s₅₇ and s₅₈ respectively that is arranged on a top side thereof, i.e. where piezoelectric actuators 1521, 1522, 1523 and 1524 are mechanically linked to the flexible cantilevers. The beam members s₅₁, s₅₂, s₅₃, s₅₄, s₅₅, s₅₆, s₅₇, s₅₇ and s₅₈ thus reduce bending of flexible cantilevers in directions parallel to the first edge side e1, such that the first edge side e1 is held relatively parallel to a frame part 1510 of the support structure throughout flexion movements of the flexible cantilevers between first and second extreme positions. The frame part 1510 surrounds the flexible cantilevers 221, 222, 223 and 224.

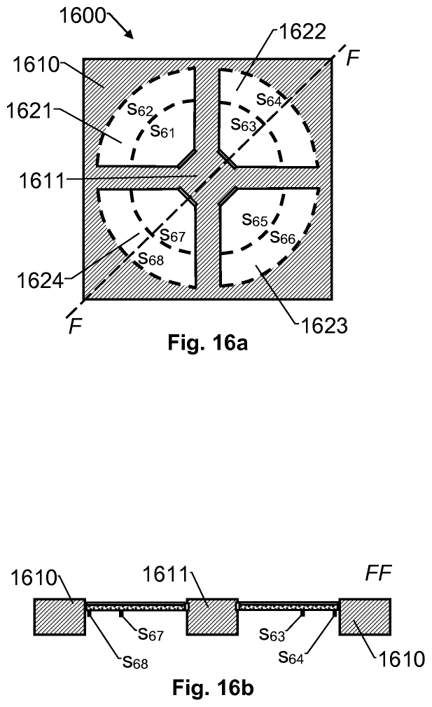

FIG. 16a shows a top view of the MEMS-based micro speaker corresponding to the embodiment of FIG. 3a, and FIG. 16b shows a section side view corresponding to FIG. 3b, however where the flexible cantilevers contain a respective set of beam members s₆₁, s₆₂, s₆₃, s₆₄, s₆₅, s₆₆, s₆₇ and s₆₈ respectively that is arranged in parallel with the first edge side e1 that is arranged on a bottom side thereof. The beam members s₆₁, s₆₂, s₆₃, s₆₄, s₆₅, s₆₆, s₆₇ and s₆₈ thus reduce bending of flexible cantilevers in directions parallel to the first edge side e11, such that the first edge side e11 is held relatively parallel to a frame part 1610 of the support structure throughout flexion movements of the flexible cantilevers between first and second extreme positions. Analogous to the above, the frame part 1610 surrounds the flexible cantilevers.

Of course, according to the invention, in any of the embodiments, the above beam members may be arranged on either, or both, the top and bottom sides of the flexible cantilevers. FIGS. 14a to 16b merely illustrate a few exemplifying designs.

Variations to the disclosed embodiments can be understood and effected by those skilled in the art in practicing the claimed invention, from a study of the drawings, the disclosure, and the appended claims.

The term “comprises/comprising” when used in this specification is taken to specify the presence of stated features, integers, steps or components. The term does not preclude the presence or addition of one or more additional elements, features, integers, steps or components or groups thereof. The indefinite article “a” or “an” does not exclude a plurality. In the claims, the word “or” is not to be interpreted as an exclusive or (sometimes referred to as “XOR”). On the contrary, expressions such as “A or B” covers all the cases “A and not B”, “B and not A” and “A and B”, unless otherwise indicated. The mere fact that certain measures are recited in mutually different dependent claims does not indicate that a combination of these measures cannot be used to advantage. Any reference signs in the claims should not be construed as limiting the scope.

It is also to be noted that features from the various embodiments described herein may freely be combined, unless it is explicitly stated that such a combination would be unsuitable.

The invention is not restricted to the described embodiments in the figures, but may be varied freely within the scope of the claims.

1. A MEMS-based micro speaker comprising:
a support structure; and
a flexible cantilever configured to be deflected in response to a first control signal influencing at least one first piezoelectric actuator mechanically linked to the flexible cantilever, the flexible cantilever having a base side and at least one edge side, the base side comprising an attachment section in which the flexible cantilever is fixed to the support structure, and the at least one edge side being movable relative to the support structure,
wherein the support structure comprises a frame part that surrounds the flexible cantilever, and wherein
the flexible cantilever comprises flat top and bottom surfaces that are parallel to one another and have equally shaped and sized outlines which generally widen from the base side towards the at least one edge side.

2. The MEMS-based micro speaker according to claim 1, wherein the frame part adjoins each of the at least one edge side of the flexible cantilever.

3. The MEMS-based micro speaker according to claim 2, comprising a flexible polymer membrane, which covers a gap distance between said each of the at least one edge side of the flexible cantilever and the frame part of the support structure.

4. The MEMS-based micro speaker according to claim 1, wherein the base side has a rectilinear outline.

5. The MEMS-based micro speaker according to claim 1, wherein the flexible cantilever comprises a first edge side that has a curved outline.

6. The MEMS-based micro speaker according to claim 4, wherein the flexible cantilever comprises a first edge side that has a rectilinear outline, which first edge side is parallel to the base side.

7. The MEMS-based micro speaker according to claim 4, wherein the flexible cantilever comprises second and third edge sides, which second and third edge sides connect the first edge side with the base side.

8. The MEMS-based micro speaker according to claim 6, wherein the first edge side is longer than the base side.

9. The MEMS-based micro speaker according to claim 1, comprising two instances of said flexible cantilever each of which at least two instances is fixed to a frame part of the support structure via a respective attachment section.

10. The MEMS-based micro speaker according to claim 1, comprising at least two instances of said flexible cantilever each of which at least two instances is fixed to a central part of the support structure via a respective attachment section.

11. The MEMS-based micro speaker according to claim 10, wherein the central part of the support structure is connected to a frame part of the support structure via at least two flexible support arms, which each is mechanically linked to a respective at least one second piezoelectric actuator controllable in response to at least one second control signal so as to influence a position of the central part of the support structure along an axis perpendicular to a plane represented by the frame part of the support structure.

12. The MEMS-based micro speaker according to claim 11, comprising at least two instances of said flexible cantilever, which each is fixed to the central part the support structure via a respective attachment section

13. The MEMS-based micro speaker according to claim 11, wherein each of the at least two flexible support arms is configured to be deflected in response to the at least one second control signal such that:
in a first extreme positioning of the at least two instances of flexible cantilevers the at least one edge side thereof reaches a first maximum distance from the frame part of the support structure in a first direction parallel to the axis perpendicular to the plane represented by the frame part of the support structure, and
in a second extreme positioning of the at least two instances of flexible cantilevers the at least one edge side thereof reaches a second maximum distance from the frame part of the support structure in a second direction parallel to the axis perpendicular to the plane represented by the frame part of the support structure, which second direction is opposite to the first direction.

14. The MEMS-based micro speaker according to claim 1, comprising a flexible polymer membrane covering the flexible cantilever and the support structure, which flexible polymer membrane is arranged to prevent fluid leakage between the flexible cantilever and the support structure such that:
in a first extreme positioning of the flexible cantilever, the flexible polymer membrane is folded to form a fold between the at least one edge side of the flexible cantilever and the frame part of the support structure, and
in a second extreme positioning of the flexible cantilever, the flexible polymer membrane is unfolded to cover a spacing between the at least one edge side of the flexible cantilever and the frame part of the support structure.

15. The MEMS-based micro speaker according to claim 1, wherein:
the at least one edge side of the flexible cantilever is movable relative to the support structure between first and second extreme positionings with respect to first and second distances along an axis perpendicular to a plane represented by the frame part of the support structure; and
said frame part is arranged relative to the attachment section of the flexible cantilever and has such an extension along said axis that in each of the first and second extreme positionings a gap distance between said frame part and the at least one edge side is less than a threshold distance.

16. The MEMS-based micro speaker according to claim 3, wherein the flexible cantilever comprises at least one beam member arranged in parallel with the first edge side, which at least one beam member is configured to reduce bending of flexible cantilever in directions parallel to the first edge side.

17. The MEMS-based micro speaker according to claim 1, wherein the at least one first piezoelectric actuator comprises at least one polarized piezoelectric layer and one intrinsic layer, which layers are configured to cause the at least one first piezoelectric actuator to:
bend in a first direction in response to the first control signal applied between terminals connected to the at least one polarized piezoelectric layer and a point electrically isolated therefrom by the intrinsic layer respectively, if the first control signal carries a voltage of a first magnitude relative to a reference voltage, and
bend in a second direction opposite to the first direction in response to the first control signal applied between the terminals, if the first control signal carries a voltage of a second magnitude being opposite to the first magnitude in relation to the reference voltage.
